(19) United States
(12) Patent Application Publication
(10) Pub. No.: US 2021/0082808 A1
(43) Pub. Date: Mar. 18, 2021

(54) SEMICONDUCTOR MEMORY DEVICE

(71) Applicant: Kioxia Corporation, Minato-ku (JP)

(72) Inventor: Hiroyasu SATO, Yokkaichi (JP)

(73) Assignee: Kioxia Corporation, Minato-ku (JP)

(21) Appl. No.: 16/801,207

(22) Filed: Feb. 26, 2020

(30) Foreign Application Priority Data
Sep. 18, 2019 (JP) 2019-169908

(51) Int. Cl. H01L 23/522; H01L 27/1157; H01L 27/11582; H01L 23/528

(52) U.S. Cl. CPC H01L 23/5226; H01L 23/5283; H01L 27/11582; H01L 27/1157

(57) ABSTRACT

A semiconductor memory device according to an embodiment includes a substrate, a first conductive layer provided across a first region and a second region of the substrate, a second conductive layer disposed above the first conductive layer to be away from the first conductive layer, the second conductive layer being provided across the first region and the second region, a pillar passing through the first conductive layer and the second conductive layer in a first direction in the second region, the pillar including a semiconductor film, a charge storage film provided between the semiconductor film and the first conductive layer and between the semiconductor film and the second conductive layer, a first insulating layer provided between the first conductive layer and the second conductive layer in the first region, the first insulating layer containing a first insulating material, the first insulating material being silicon oxide, a second insulating layer provided between the first conductive layer and the second conductive layer in the second region, the second insulating layer containing a second insulating material having a higher dielectric constant than a dielectric constant of the silicon oxide, a dividing film configured to divide the first conductive layer, the second conductive layer, and the second insulating layer in a second direction intersecting with the first direction across the first region and the second region, and a third insulating layer provided between the dividing film and the second insulating layer, the third insulating layer containing the first insulating material, the third insulating layer being in contact with the first insulating layer.

### CROSS-REFERENCE TO RELATED APPLICATION

This application is based upon and claims the benefit of priority from Japanese Patent Application No. 2019-169908, filed on Sep. 18, 2019, the entire contents of which are incorporated herein by reference.

### FIELD

Embodiments described herein relate generally to a semiconductor memory device.

### BACKGROUND

A high-capacity nonvolatile memory is under active development. The memory of this type is capable of low voltage and low current operation, high-speed switching, and downscaling and high integration of memory cells.

In a high-capacity memory array, a large number of metal interconnect lines, called bit lines and word lines, are arranged. In writing in a single memory cell, voltage is applied to a bit line and a word line connected to the cell. A memory device in which memory cells are arranged three-dimensionally has been proposed with use of a stacked body in which insulating layers and conductive layers serving as word lines are alternately stacked.

### BRIEF DESCRIPTION OF THE DRAWINGS

FIG. 1 is an equivalent circuit diagram of a semiconductor memory device according to a first embodiment;

FIG. 2 is a schematic cross-sectional view of the semiconductor memory device according to the first embodiment;

FIG. 3 is a schematic cross-sectional view of a stepped region and a memory cell region in the semiconductor memory device according to the first embodiment;

FIG. 4 is a schematic cross-sectional view of the vicinity of memory pillars of the semiconductor memory device according to the first embodiment;

FIG. 5 is a schematic cross-sectional view of the vicinity of the memory pillars of the semiconductor memory device according to the first embodiment;

FIGS. 6A to 6F are schematic views illustrating cross sections of the semiconductor memory device being manufactured in a method for manufacturing the main part of the semiconductor memory device according to the first embodiment;

FIG. 7 is a schematic cross-sectional view of the vicinity of memory pillars of a semiconductor memory device according to a second embodiment;

FIG. 8 is a schematic cross-sectional view of the vicinity of memory pillars of a semiconductor memory device according to a third embodiment;

FIG. 9 is a schematic cross-sectional view of the vicinity of memory pillars of a semiconductor memory device according to a fourth embodiment;

FIG. 10 is a schematic cross-sectional view of the vicinity of memory pillars of a semiconductor memory device according to a fifth embodiment;

FIG. 11 is a schematic cross-sectional view of the vicinity of memory pillars of a semiconductor memory device according to a sixth embodiment;

FIG. 12 is a schematic cross-sectional view of the vicinity of memory pillars of a semiconductor memory device according to a seventh embodiment; and

FIG. 13 is a schematic cross-sectional view of the vicinity of memory pillars of a semiconductor memory device according to an eighth embodiment.

### DETAILED DESCRIPTION

A semiconductor memory device according to an embodiment includes a substrate, a first conductive layer provided across a first region and a second region of the substrate, a second conductive layer disposed above the first conductive layer to be away from the first conductive layer, the second conductive layer being provided across the first region and the second region, a pillar passing through the first conductive layer and the second conductive layer in a first direction in the second region, the pillar including a semiconductor film, a charge storage film provided between the semiconductor film and the first conductive layer and between the semiconductor film and the second conductive layer, a first insulating layer provided between the first conductive layer and the second conductive layer in the first region, the first insulating layer containing a first insulating material, the first insulating material being silicon oxide, a second insulating layer provided between the first conductive layer and the second conductive layer in the second region, the second insulating layer containing a second insulating material having a higher dielectric constant than a dielectric constant of the silicon oxide, a dividing film configured to divide the first conductive layer, the second conductive layer, and the second insulating layer in a second direction intersecting with the first direction across the first region and the second region, and a third insulating layer provided between the dividing film and the second insulating layer, the third insulating layer containing the first insulating material, the third insulating layer being in contact with the first insulating layer.

Embodiments will be described below with reference to the drawings. Note that, in the drawings, identical or similar reference numerals are given to identical or similar components.

In the present specification, in order to illustrate positional relationships among components, an upper direction in the drawings is expressed as “upper” while a lower direction in the drawings is expressed as “lower”. In the present specification, the concepts “upper” and “lower” are not necessarily terms indicating a relationship with the direction of gravity.

### First Embodiment

A semiconductor memory device according to the embodiment includes a substrate, a first conductive layer provided across a first region and a second region of the substrate, a second conductive layer disposed above the first conductive layer to be away from the first conductive layer, the second conductive layer being provided across the first region and the second region, a pillar passing through the first conductive layer and the second conductive layer in a first direction in the second region, the pillar including a semiconductor film, a charge storage film provided between the semiconductor film and the first conductive layer and between the semiconductor film and the second conductive layer, a first insulating layer provided between the first conductive layer and the second conductive layer in the first region, the first insulating layer containing a first insulating material, the first insulating material being silicon oxide, a second insulating layer provided between the first conductive layer and the second conductive layer in the second region, the second insulating layer containing a second insulating material having a higher dielectric constant than a dielectric constant of the silicon oxide, a dividing film configured to divide the first conductive layer, the second conductive layer, and the second insulating layer in a second direction intersecting with the first direction across the first region and the second region, and a third insulating layer provided between the dividing film and the second insulating layer, the third insulating layer containing the first insulating material, the third insulating layer being in contact with the first insulating layer.

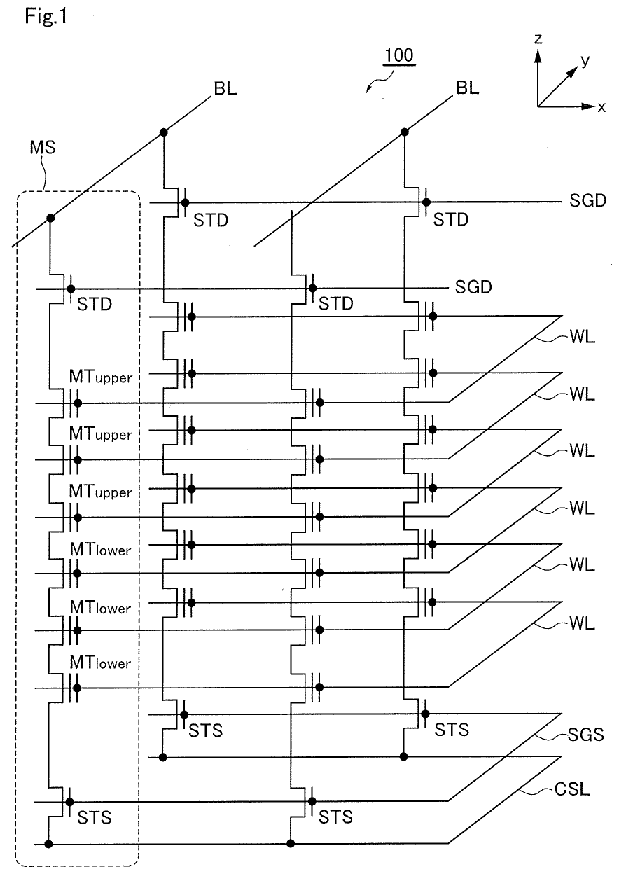

FIG. 1 is an equivalent circuit diagram of a semiconductor memory device 100 according to the embodiment.

The semiconductor memory device 100 according to the embodiment is a three-dimensional NAND flash memory in which memory cells have been disposed three-dimensionally.

As illustrated in FIG. 1, the semiconductor memory device 100 includes a plurality of word lines WL, a common source line CSL, a source selection gate line SGS, a plurality of drain selection gate lines SGD, a plurality of bit lines BL, and a plurality of memory strings MS.

Each of the memory strings MS includes a source selection transistor STS, a plurality of memory cell transistors MT_{lower} and MTᵤₚₚₑᵣ serving as memory cell transistors MT, and a drain selection transistor STD, which are connected in series between the common source line CSL and the bit line BL.

Note that the number of the word lines WL, the number of the bit lines BL, the number of the memory strings MS, the number of the memory cell transistors MT, and the number of the drain selection gate lines SGD are not limited to those illustrated in FIG. 1.

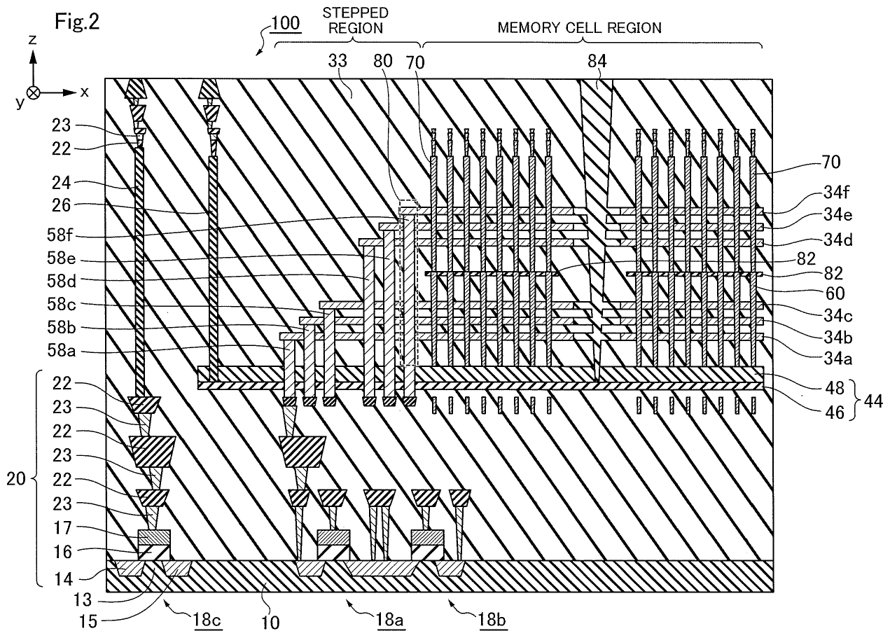

FIG. 2 is a schematic cross-sectional view of the semiconductor memory device according to the embodiment.

The source selection gate line SGS, the drain selection gate lines SGD, the source selection transistors STS, the drain selection transistors STD, the bit lines BL, and a barrier metal are not illustrated in FIG. 2.

A substrate 10 is a semiconductor substrate, for example. The substrate 10 is a silicon substrate, for example. In FIG. 2, the substrate 10 is disposed in order for the substrate plane to be parallel to an xy plane. Here, an x axis, a y axis perpendicular to the x axis, and a z axis perpendicular to the x axis and the y axis are defined. It is assumed that the surface of the substrate 10 is disposed in parallel with the xy plane. A z direction parallel to the z axis is an example of a first direction, and an x direction parallel to the x axis is an example of a second direction.

A plurality of transistors 18 are provided to the substrate 10. For example, transistors 18a, 18b, and 18c are provided to the substrate 10. Each of the transistors 18a, 18b, and 18c includes a source region 14 provided in an upper layer portion of the substrate 10, a drain region 15 provided in the upper layer portion of the substrate 10, a semiconductor region 13 provided in the upper layer portion of the substrate 10 between the source region 14 and the drain region 15, a gate insulating film 16 provided on the semiconductor region 13, and a gate electrode 17 provided on the gate insulating film 16. The transistors 18a, 18b, and 18c are field-effect transistors, for example. The transistors 18a, 18b, and 18c are used for driving of a three-dimensional NAND flash memory, for example. The transistors 18a, 18b, and 18c are examples of semiconductor elements. In the example in FIG. 2, the transistors 18a, 18b, and 18c are illustrated as the plurality of transistors 18.

A first insulating layer 33 is provided on the substrate 10. The first insulating layer 33 contains silicon oxide (an example of a first insulating material), for example.

An integrated circuit 20 is provided within the substrate 10 and within the first insulating layer 33. The integrated circuit 20 includes the plurality of transistors 18, contacts 23 electrically connected to the plurality of transistors 18, and interconnect lines 22 electrically connected to the contacts 23.

A buried source line 44 is provided above the integrated circuit 20. The buried source line 44 includes a buried source line lower layer portion 46 containing tungsten (W) and a buried source line upper layer portion 48 containing polysilicon, for example. The buried source line 44 is supplied with electric potential from the integrated circuit 20. The buried source line 44 corresponds to the common source line CSL in FIG. 1.

Above the substrate 10, a plurality of plate-like conductive layers 34 extending in parallel with the substrate surface of the substrate 10 are provided across a stepped region (an example of a first region) and a memory cell region (an example of a second region). For example, conductive layers 34a, 34b, 34c, 34d, 34e, and 34f serving as the plurality of conductive layers 34 are stacked with the first insulating layer 33 interposed between the conductive layers. In the semiconductor memory device 100 illustrated in FIG. 2, the plurality of conductive layers 34 are formed in a stepped manner in the x direction in FIG. 2. Specifically, the conductive layers 34 are disposed as follows.

The conductive layer 34b is a plate-like conductive layer disposed above the conductive layer 34a to be away from the conductive layer 34a in a stepped form in order for the end portion of the conductive layer 34a to protrude in the stepped region, the conductive layer 34b extending in parallel with the conductive layer 34a.

The conductive layer 34c (an example of a first conductive layer) is a plate-like conductive layer disposed above the conductive layer 34b to be away from the conductive layer 34b in a stepped form in order for the end portion of the conductive layer 34b to protrude in the stepped region, the conductive layer 34c extending in parallel with the conductive layer 34b.

The conductive layer 34d (an example of a second conductive layer) is a plate-like conductive layer disposed above the conductive layer 34c to be away from the conductive layer 34c in a stepped form in order for the end portion of the conductive layer 34c to protrude in the stepped region, the conductive layer 34d extending in parallel with the conductive layer 34c.

The conductive layer 34e is a plate-like conductive layer disposed above the conductive layer 34d to be away from the conductive layer 34d in a stepped form in order for the end portion of the conductive layer 34d to protrude in the stepped region, the conductive layer 34e extending in parallel with the conductive layer 34d.

The conductive layer 34f is a plate-like conductive layer disposed above the conductive layer 34e to be away from the conductive layer 34e in a stepped form in order for the end portion of the conductive layer 34e to protrude in the stepped region, the conductive layer 34f extending in parallel with the conductive layer 34e.

The conductive layers 34a, 34b, 34c, 34d, 34e, and 34f function as the word lines WL. Note that the positional relationship between the substrate 10 and the conductive layers 34a, 34b, 34c, 34d, 34e, and 34f is not limited to that described in the present embodiment.

Although there are six conductive layers 34 in the semiconductor memory device 100 according to the embodiment, the number of the conductive layers 34 is not limited to this.

Electrode members 58 are provided in the stepped region. In the example in FIG. 2, electrode members 58a, 58b, 58c, 58d, 58e, and 58f are provided, for example. Each of the electrode members 58 functions as a contact connecting the interconnect line 22 on the substrate side to the corresponding conductive layer 34.

The electrode member 58a is connected to the conductive layer 34a at a position at which the conductive layer 34a protrudes further than the conductive layers 34b, 34c, 34d, 34e, and 34f in the stepped region. The electrode member 58a extends toward the substrate (the “substrate” here includes the integrated circuit 20 formed on the substrate 10) from the conductive layer 34a.

The electrode member 58b is connected to the conductive layer 34b at a position at which the conductive layer 34b protrudes further than the conductive layers 34c, 34d, 34e, and 34f in the stepped region. The electrode member 58b extends toward the substrate (the “substrate” here includes the integrated circuit 20 formed on the substrate 10) from the conductive layer 34b and passes through the conductive layer 34a provided further on the lower layer side than the conductive layer 34b.

The electrode member 58c is connected to the conductive layer 34c at a position at which the conductive layer 34c protrudes further than the conductive layers 34d, 34e, and 34f in the stepped region. The electrode member 58c extends toward the substrate (the “substrate” here includes the integrated circuit 20 formed on the substrate 10) from the conductive layer 34c and passes through the conductive layers 34a and 34b provided further on the lower layer side than the conductive layer 34c.

The electrode member 58d is connected to the conductive layer 34d at a position at which the conductive layer 34d protrudes further than the conductive layers 34e and 34f in the stepped region. The electrode member 58d extends toward the substrate (the “substrate” here includes the integrated circuit 20 formed on the substrate 10) from the conductive layer 34d and passes through the conductive layers 34a, 34b, and 34c provided further on the lower layer side than the conductive layer 34d.

The electrode member 58e is connected to the conductive layer 34e at a position at which the conductive layer 34e protrudes further than the conductive layer 34f in the stepped region. The electrode member 58e extends toward the substrate (the “substrate” here includes the integrated circuit 20 formed on the substrate 10) from the conductive layer 34e and passes through the conductive layers 34a, 34b, 34c, and 34d provided further on the lower layer side than the conductive layer 34e.

The electrode member 58f is connected to the conductive layer 34f in the stepped region. The electrode member 58f extends toward the substrate (the “substrate” here includes the integrated circuit 20 formed on the substrate 10) from the conductive layer 34f and passes through the conductive layers 34a, 34b, 34c, 34d, and 34e provided further on the lower layer side than the conductive layer 34f.

Tungsten, titanium nitride, or copper is preferably used as a material for the conductive layers 34a, 34b, 34c, 34d, 34e, and 34f, for example. Note that a conductive layer such as another metal, a metal semiconductor compound, and a semiconductor may be used for the conductive layers 34a, 34b, 34c, 34d, 34e, and 34f.

Tungsten, titanium nitride, or copper is preferably used as a material for the electrode members 58a, 58b, 58c, 58d, 58e, and 58f (and the aforementioned other respective not-illustrated electrode members), for example. Note that a conductive layer such as another metal, a metal semiconductor compound, and a semiconductor may be used for the electrode members 58a, 58b, 58c, 58d, 58e, and 58f.

Note that a way to connect the conductive layer 34 to the electrode member 58 is not limited to this.

Memory pillars 60 pass through the conductive layers 34a, 34b, and 34c in the memory cell region. Memory pillars 70 pass through the conductive layers 34d, 34e, and 34f in the memory cell region.

Meanwhile, as described below, in the semiconductor memory device 100 illustrated in FIG. 2, the conductive layers 34a, 34b, and 34c are formed, not-illustrated holes penetrating the conductive layers 34a, 34b, and 34c for forming the memory pillars 60 are formed, the conductive layers 34d, 34e, and 34f are formed, and not-illustrated holes penetrating the conductive layers 34d, 34e, and 34f for forming the memory pillars 70 are formed. In a case in which the number of the conductive layers 34 is large to cause the hole in a direction perpendicular to the substrate surface to be long, it is difficult to make the diameter of the upper portion of the hole equal to the diameter of the lower portion of the hole. This may cause the diameter of the lower portion of the hole to be excessively shorter than the diameter of the upper portion of the hole. Under such circumstances, a single hole penetrating the conductive layers 34a, 34b, 34c, 34d, 34e and 34f is not formed, but a hole penetrating the conductive layers 34a, 34b, and 34c and a hole penetrating the conductive layers 34d, 34e, and 34f are formed separately.

Meanwhile, in a case in which the hole penetrating the conductive layers 34a, 34b, and 34c and the hole penetrating the conductive layers 34d, 34e, and 34f are formed separately as described above, there is a case in which the distance in the direction perpendicular to the substrate surface between the conductive layer 34c and the conductive layer 34d is longer than the distance between the conductive layer 34a and the conductive layer 34b, the distance between the conductive layer 34b and the conductive layer 34c, the distance between the conductive layer 34d and the conductive layer 34e, and the distance between the conductive layer 34e and the conductive layer 34f in the direction perpendicular to the substrate surface (z direction). However, the distance between the conductive layer 34c and the conductive layer 34d in the direction perpendicular to the substrate surface (z direction) may be equal to or shorter than the distance between the conductive layer 34a and the conductive layer 34b, the distance between the conductive layer 34b and the conductive layer 34c, the distance between the conductive layer 34d and the conductive layer 34e, and the distance between the conductive layer 34e and the conductive layer 34f in the direction perpendicular to the substrate surface (z direction).

A second insulating layer 82 is provided in parallel with the substrate surface between the conductive layer 34c and the conductive layer 34d in the memory cell region. The second insulating layer 82 contains a second insulating material having a higher dielectric constant than that of silicon oxide. Examples of the second insulating material are AlOₓ (aluminum oxide), ZrOₓ (zirconium oxide), HfOₓ (hafnium oxide), and HfSiOₓ (hafnium silicate).

A via 24 is electrically connected to the transistor 18c provided in the substrate 10 via the interconnect lines 22 and the contacts 23.

The electrode members 58a, 58b, 58c, 58d, 58e and 58f are electrically connected to the transistor 18a and the transistor 18b via the interconnect lines 22 and the contacts 23.

A via 26 connected to the buried source line 44 is electrically connected to a not-illustrated transistor (an element similar to the transistor 18) via the interconnect lines 22 and the contacts 23.

A reinforcing member 80 is provided to extend perpendicularly to the substrate surface in the stepped region. Silicon oxide is preferably used as a material for the reinforcing member 80, for example. As described below, a silicon nitride layer is first formed instead of each of the conductive layers 34, and the silicon nitride layer is then replaced with the conductive layer 34. Since the layers are temporarily hollowed at this time, the reinforcing member 80 is disposed to maintain a stacked structure.

A third dividing film 84 is a portion provided with a groove for use in introduction and discharge of a wet etching solution for use in formation of the conductive layer 34 and the electrode member 58 and for use in introduction of a conductive material at the time of manufacture of the semiconductor memory device 100 described below. The groove after the introduction of the conductive material is filled with silicon oxide or the like, and the third dividing film 84 is formed.

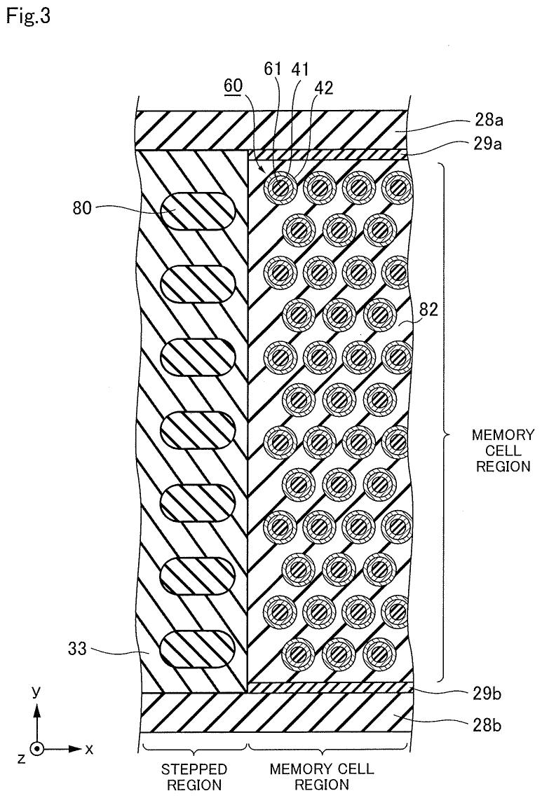

FIG. 3 is a schematic cross-sectional view of a stepped region and a memory cell region in the semiconductor memory device according to the first embodiment; FIG. 3 is a schematic cross-sectional view illustrating a plane parallel to the xy plane including the upper surface of the second insulating layer 82.

In a plane parallel to the substrate surface, a first dividing film 28a (an example of a dividing film) and a second dividing film 28b are provided across the stepped region and the memory cell region and divide the conductive layers 34a, 34b, 34c, 34d, 34e, and 34f from the second insulating layer 82 in the x direction. Each of the first dividing film 28a and the second dividing film 28b is a portion provided with a groove for use in introduction and discharge of a wet etching solution for use in formation of the conductive layer 34 and the electrode member 58 and for use in introduction of a conductive material at the time of manufacture of the semiconductor memory device 100 described below. The grooves after the introduction of the conductive material are filled with silicon oxide or the like, and the first dividing film 28a and the second dividing film 28b are formed.

A first insulating region (an example of a third insulating layer) 29a is provided between the first dividing film 28a and the second insulating layer 82 and is in contact with the second insulating layer 82. A second insulating region 29b is provided between the second dividing film 28b and the second insulating layer 82 and is in contact with the second insulating layer 82. The first insulating region 29a and the second insulating region 29b contain a first insulating material, which is silicon oxide, for example. For example, in a case in which the second insulating layer 82 contains AlOₓ, the second insulating layer 82 may be etched by a wet etching solution such as phosphoric acid (H₃PO₄) introduced into the grooves provided in the first dividing film 28a and the second dividing film 28b. Therefore, in order to prevent the second insulating layer 82 from being etched, the first insulating region 29a and the second insulating region 29b are provided.

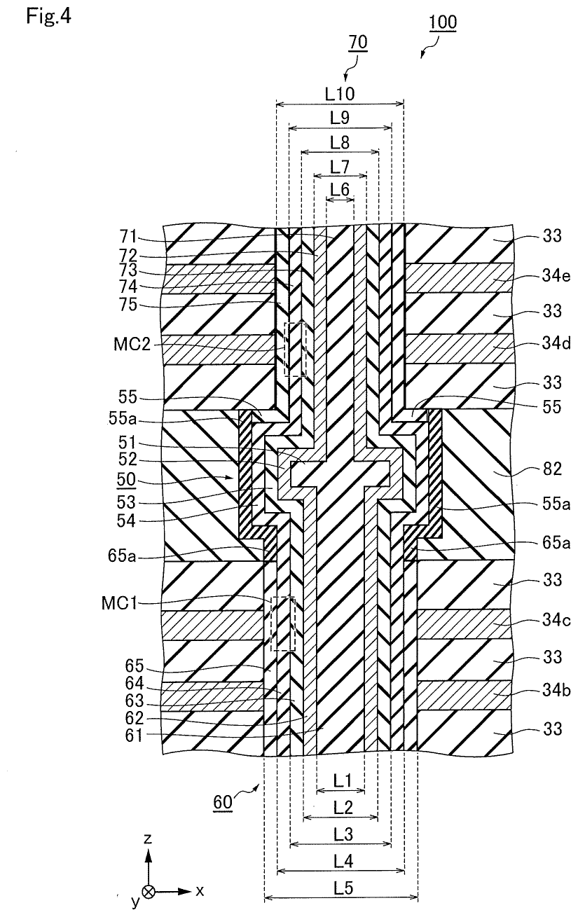

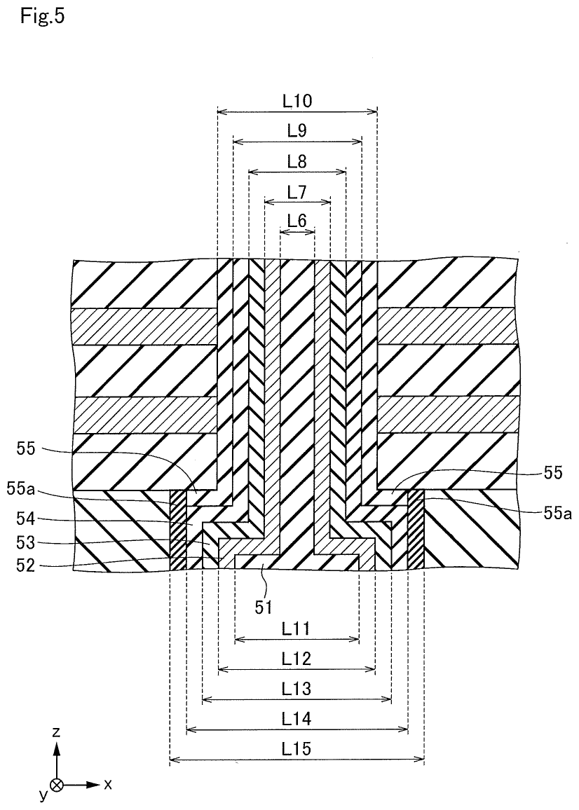

FIGS. 4 and 5 are schematic cross-sectional views of the vicinity of the memory pillar 60, the memory pillar 70, and a connection unit 50 of the semiconductor memory device 100 according to the embodiment.

The memory pillar 60 includes a first core member 61, a first signal line 62 (an example of a first pillar portion or a pillar), a first tunnel insulating film 63, a first charge storage film 64 (an example of a charge storage film), and a first block insulating film 65 (an example of an insulating film).

The first core member 61 is provided in the memory pillar 60. The first core member 61 is silicon oxide, for example.

The first signal line 62 including a semiconductor film (an example of a first semiconductor film) is provided around the first core member 61 in the memory pillar 60. The first signal line 62 is a pillar containing a semiconductor material such as silicon. The first signal line 62 is electrically connected to the buried source line 44.

The first tunnel insulating film 63 is provided around the first signal line 62. The first charge storage film 64 is provided around the first tunnel insulating film 63. The first block insulating film 65 is provided around the first charge storage film 64.

Although the first tunnel insulating film 63 has insulating properties, the first tunnel insulating film 63 is an insulating film through which current flows due to application of predetermined voltage. The first tunnel insulating film 63 contains silicon oxide, for example.

The first charge storage film 64 is a film containing a material capable of storing electric charge. The first charge storage film 64 contains silicon nitride, for example.

The first block insulating film 65 is a film suppressing flow of electric charge between the first charge storage film 64 and the conductive layer 34. The first block insulating film 65 contains silicon oxide, for example.

A portion circled with the dotted line in FIG. 4 is a first memory cell MC1. The first memory cell MC1 is provided between the conductive layer 34 and the first signal line 62 and includes the first charge storage film 64.

The memory pillar 70 is provided above the memory pillar 60. The memory pillar 70 includes a second core member 71, a second signal line 72, a second tunnel insulating film 73, a second charge storage film 74 (an example of a charge storage film), and a second block insulating film 75 (an example of an insulating film).

The second core member 71 is provided in the memory pillar 70. The second core member 71 is silicon oxide, for example.

The second signal line 72 (an example of a second pillar portion or a pillar) including a semiconductor film (an example of a second semiconductor film) is provided around the second core member 71 in the memory pillar 70.

The second signal line 72 is a pillar containing a semiconductor material such as silicon. The second signal line 72 is electrically connected to the first signal line 62 via a below-mentioned third signal line 52 (an example of a third pillar portion or a pillar) including a semiconductor film and is electrically connected to the buried source line 44 (FIG. 2).

The second tunnel insulating film 73 is provided around the second signal line 72. The second charge storage film 74 is provided around the second tunnel insulating film 73. The second block insulating film 75 is provided around the second charge storage film 74.

Although the second tunnel insulating film 73 has insulating properties, the second tunnel insulating film 73 is an insulating film through which current flows due to application of predetermined voltage. The second tunnel insulating film 73 contains silicon oxide, for example.

The second charge storage film 74 is a film containing a material capable of storing electric charge. The second charge storage film 74 contains silicon nitride, for example.

The second block insulating film 75 is a film suppressing flow of electric charge between the second charge storage film 74 and the conductive layer 34. The second block insulating film 75 contains silicon oxide, for example.

A portion circled with the dotted line in FIG. 4 is a second memory cell MC2. The second memory cell MC2 is provided between the conductive layer 34 and the second signal line 72 and includes the second charge storage film 74.

The connection unit 50 is provided between the memory pillar 60 and the memory pillar 70. The connection unit 50 includes a third core member 51, a third signal line 52, an insulating film 53, an insulating film 54, and an insulating film 55 (an example of a third insulating film).

The third core member 51 is provided between the first core member 61 and the second core member 71 and is in contact with the first core member 61 and the second core member 71. The third core member 51 is silicon oxide, for example.

The third signal line 52 including a semiconductor film is provided around the third core member 51. The third signal line 52 is a pillar containing a semiconductor material such as silicon. The third signal line 52 is provided between the first signal line 62 and the second signal line 72 and is in contact with the first signal line 62 and the second signal line 72. The third signal line 52 electrically connects the first signal line 62 to the second signal line 72.

The insulating film 53 is provided around the third signal line 52. The insulating film 53 contains silicon oxide, for example. The insulating film 53 contains the same material as those for the first tunnel insulating film 63 and the second tunnel insulating film 73, for example. The insulating film 53 is in contact with the first tunnel insulating film 63 and the second tunnel insulating film 73.

The insulating film 54 is provided around the insulating film 53. The insulating film 54 contains silicon nitride, for example.

The insulating film 55 is provided around the insulating film 54. The insulating film 55 contains silicon oxide, for example.

A diameter L₁ of the first core member 61 in the xy plane is longer than a diameter L₆ of the second core member 71 in the xy plane. A diameter L₂ of the first signal line 62 in the xy plane is longer than a diameter L₇ of the second signal line 72 in the xy plane. A diameter L₃ of the first tunnel insulating film 63 in the xy plane is longer than a diameter L₈ of the second tunnel insulating film 73 in the xy plane. A diameter L₄ of the first charge storage film 64 in the xy plane is longer than a diameter L₉ of the second charge storage film 74 in the xy plane. A diameter L₅ of the first block insulating film 65 in the xy plane is longer than a diameter L₁₀ of the second block insulating film 75 in the xy plane.

Also, a diameter L₁₁ of the third core member 51 in the xy plane is longer than the diameter L₁ of the first core member 61 in the xy plane. A diameter L₁₂ of the third signal line 52 in the xy plane is longer than the diameter L₂ of the first signal line 62 in the xy plane. A diameter L₁₃ of the insulating film 53 in the xy plane is longer than the diameter L₃ of the first tunnel insulating film 63 in the xy plane. A diameter L₁₄ of the insulating film 54 in the xy plane is longer than the diameter L₄ of the first charge storage film 64 in the xy plane. A diameter L₁₅ of the insulating film 55 in the xy plane is longer than the diameter L₅ of the first block insulating film 65 in the xy plane.

The connection unit 50 is provided for the purpose of allowing a margin for a position at which the memory pillar 70 is to be formed in order that the first memory cell MC1 in the memory pillar 60 and the second memory cell MC2 in the memory pillar 70 may function as one memory string even in a case in which the memory pillar 70 is formed to be slightly misaligned with a position immediately above the memory pillar 60. For this reason, as described above, the diameter of each member of the connection unit 50 is longer than the diameter of each corresponding member of the memory pillar 60.

The second insulating layer 82 is provided around the insulating film 55 of the connection unit 50 and is in contact with the insulating film 55. The upper surface of the second insulating layer 82 is as high as the upper surface of the insulating film 55. The lower surface of the second insulating layer 82 is provided further on the lower side than the connection unit 50 and is in contact with the first block insulating film 65.

In a third portion 55a of the insulating film 55 in contact with the second insulating layer 82, the second insulating material contained in the second insulating layer 82 is mixed. In other words, the third portion 55a of the insulating film 55 in contact with the second insulating layer 82 contains the second insulating material contained in the second insulating layer 82.

Also, in a first portion 65a of the first block insulating film 65 (an example of an insulating film) in contact with the second insulating layer 82, the second insulating material contained in the second insulating layer 82 is mixed. In other words, the first portion 65a of the first block insulating film 65 in contact with the second insulating layer 82 contains the second insulating material contained in the second insulating layer 82.

In FIGS. 4 and 5, illustration of a barrier metal is omitted.

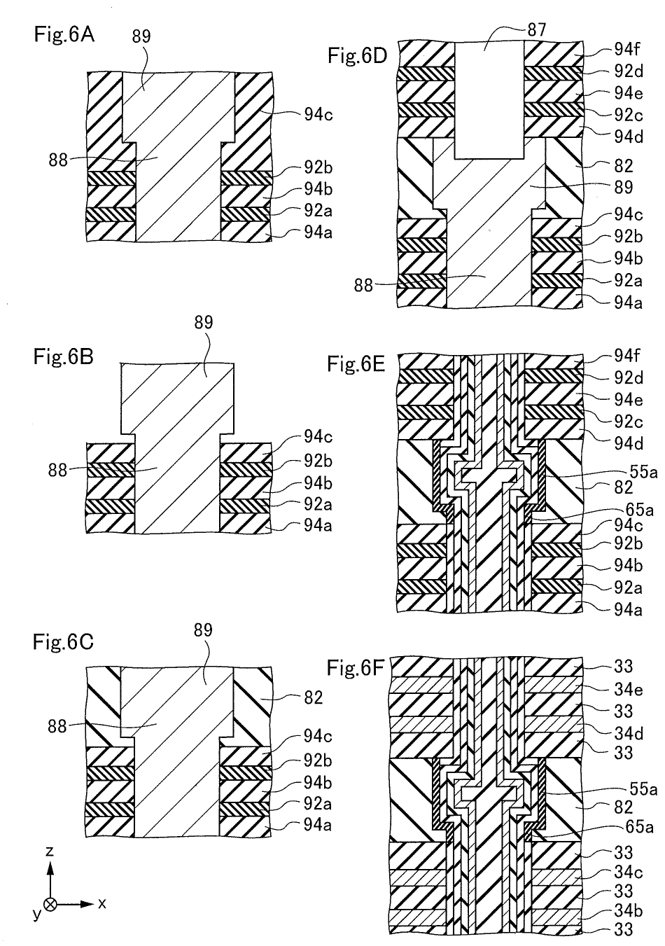

FIGS. 6A to 6F are schematic views illustrating cross sections of the semiconductor memory device being manufactured in a method for manufacturing the main part of the semiconductor memory device according to the present embodiment.

First, a stacked structure of an oxide film 94 and a nitride film 92 is formed. For example, a stacked structure of oxide films 94a, 94b, and 94c serving as the oxide film 94 and nitride films 92a and 92b serving as the nitride film 92 is formed. The oxide film 94 contains silicon oxide, for example. The nitride film 92 contains silicon nitride, for example. Subsequently, a hole penetrating the stacked structure of the oxide film 94 and the nitride film 92 is formed, and amorphous silicon 88 and amorphous silicon 89 are formed in the hole. The portion at which the amorphous silicon 88 is formed is a portion at which the memory pillar 60 is to be formed afterward. The portion at which the amorphous silicon 89 is formed is a portion at which the connection unit 50 is to be formed afterward. The amorphous silicon 89 in the oxide film 94c is formed to have a longer diameter than that of the amorphous silicon 88 formed further on the lower side than the amorphous silicon 89 (FIG. 6A).

Subsequently, the oxide film 94c is partially removed by etch back, for example, with the amorphous silicon 88 and the amorphous silicon 89 left (FIG. 6B).

Subsequently, the second insulating layer 82 is formed at the partially removed portion of the oxide film 94c (FIG. 6C).

Subsequently, a stacked structure of the oxide film 94 and the nitride film 92 is formed on the second insulating layer 82 and the amorphous silicon 89. For example, a stacked structure of oxide films 94d, 94e, and 94f serving as the oxide film 94 and nitride films 92c and 92d serving as the nitride film 92 is formed. Subsequently, a hole 87 penetrating the oxide films 94d, 94e, and 94f and the nitride films 92c and 92d and reaching the amorphous silicon 89 is formed (FIG. 6D).

Subsequently, the amorphous silicon 88 and the amorphous silicon 89 are removed with use of an aqueous solution of trimethyl-2-hydroxyethylammonium hydroxide. Subsequently, the first core member 61, the first signal line 62, the first tunnel insulating film 63, the first charge storage film 64, and the first block insulating film 65, which become the memory pillar 60, the second core member 71, the second signal line 72, the second tunnel insulating film 73, the second charge storage film 74, and the second block insulating film 75, which become the memory pillar 70, and the third core member 51, the third signal line 52, the insulating film 53, the insulating film 54, and the insulating film 55, which become the connection unit 50, are formed at the hole 87 and the removed portion of the amorphous silicon 88 and the amorphous silicon 89. Subsequently, heat treatment is performed at 1000° C. or higher, for example. Consequently, the second insulating material contained in the second insulating layer 82 is mixed into the first portion 65a of the first block insulating film 65 and the third portion 55a of the insulating film 55 (FIG. 6E).

Subsequently, the nitride film 92 is removed by wet etching via the first dividing film 28a and the second dividing film 28b (FIG. 3). Subsequently, the removed portion of the nitride film 92 is provided with a not-illustrated barrier metal and is then provided with a conductive material containing tungsten, for example. Consequently, the conductive layer 34 is formed. Subsequently, the first dividing film 28a and the second dividing film 28b are filled with an insulating material such as silicon oxide (FIG. 6F).

Next, an effect of the present embodiment will be described.

In the semiconductor memory device 100 according to the present embodiment, the second insulating layer 82 containing the second insulating material is provided. As a result, even in a case in which the hole 87 (FIG. 6D) is formed to be misaligned with the upper portion of the amorphous silicon 89, the second insulating layer 82 functions as an etching stopper, and the hole 87 can thus be prevented from reaching the oxide film 94 and the nitride film 92 residing under the second insulating layer 82. Therefore, even in a case in which the hole 87 is formed to be misaligned with the upper portion of the amorphous silicon 89, the nitride film 92 replaced with the conductive layer 34 afterward and residing under the second insulating layer 82 is not lost, and the conductive layer 34 can be formed around the memory pillar 60.

Also, when the memory pillar 70 is misaligned with the upper portion of the amorphous silicon 89, the second insulating layer 82 functions as an etching stopper. Therefore, even in a case in which the diameter of the connection unit 50 is set to be shorter than in a conventional case, the first memory cell MC1 in the memory pillar 60 and the second memory cell MC2 in the memory pillar 70 can function as one memory string.

Further, conventionally, since the third signal line 52 in the connection unit 50 is away from the conductive layers 34 provided on the upper and lower sides of the connection unit 50, it is difficult to apply a strong electric field to the third signal line 52 and to invert the state of the third signal line 52. This causes a problem in which current does not easily flow through the signal line. However, the first portion 65a of the first block insulating film 65 and the third portion 55a of the insulating film 55, generated by mixture of the second insulating material contained in the second insulating layer 82 into the first block insulating film 65 and the insulating film 55 as a result of providing and heat-treating the second insulating layer 82, are formed between the conductive layer 34 and the third signal line 52. Since the first portion 65a and the third portion 55a have a higher dielectric constant than that of silicon oxide, a strong electric field is easily applied from the conductive layer 34 to the third signal line 52. As a result, the state of the third signal line 52 is easily inverted by the electric field applied from the conductive layer 34, and the amount of current flowing through the signal line increases. Hence, the semiconductor memory device with improved reliability can be provided.

With the semiconductor memory device 100 according to the present embodiment, the semiconductor memory device with improved reliability can be provided.

### Second Embodiment

A semiconductor memory device according to the present embodiment differs from the first embodiment in that the second insulating layer 82 and the upper surface of the conductive layer 34c are in contact with each other. Here, description of contents overlapping with those of the first embodiment is omitted.

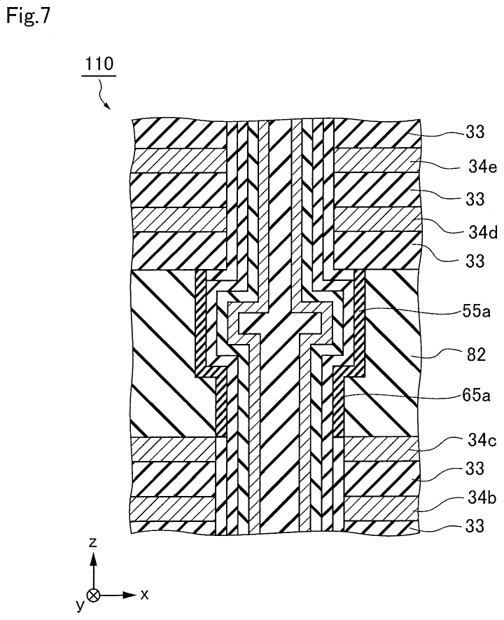

FIG. 7 is a schematic cross-sectional view of the vicinity of the memory pillars of a semiconductor memory device 110 according to the present embodiment. Illustration of a barrier metal is omitted.

With the semiconductor memory device 110 according to the present embodiment as well, the semiconductor memory device with improved reliability can be provided.

### Third Embodiment

A semiconductor memory device according to the present embodiment differs from the first and second embodiments in that the second insulating layer 82 and the second block insulating film 75 (an example of an insulating film) are in contact with each other, and in that the second insulating material is mixed in the second portion 75a of the second block insulating film 75 in contact with the second insulating layer 82. Here, description of contents overlapping with those of the first and second embodiments is omitted.

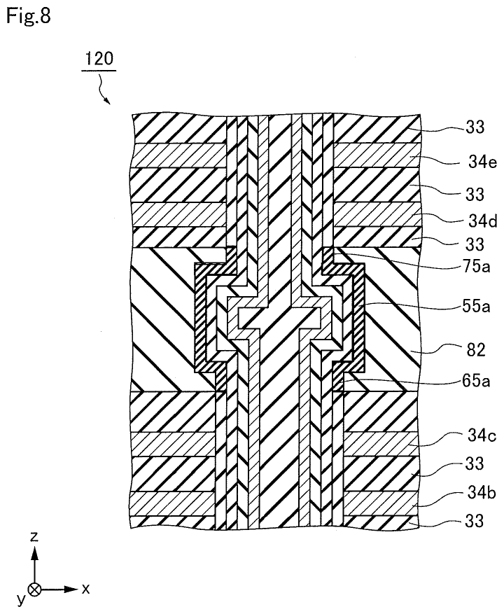

FIG. 8 is a schematic cross-sectional view of the vicinity of the memory pillars of a semiconductor memory device 120 according to the present embodiment. Illustration of a barrier metal is omitted.

With the semiconductor memory device 120 according to the present embodiment as well, the semiconductor memory device with improved reliability can be provided.

### Fourth Embodiment

A semiconductor memory device according to the present embodiment differs from the first to third embodiments in that the second insulating layer 82 and the upper surface of the conductive layer 34d are in contact with each other. Here, description of contents overlapping with those of the first to third embodiments is omitted.

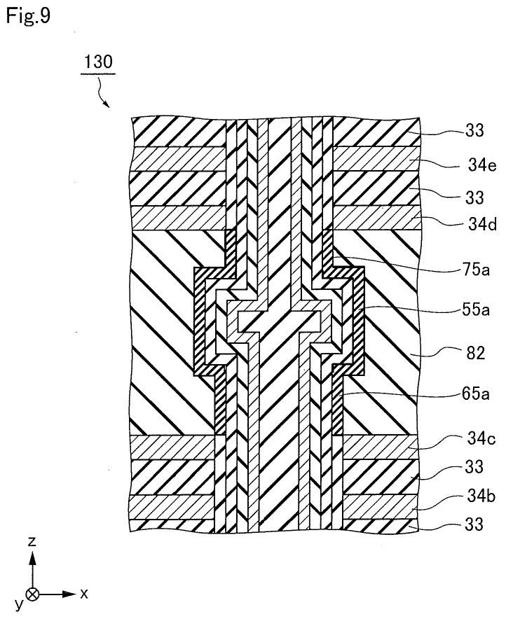

FIG. 9 is a schematic cross-sectional view of the vicinity of the memory pillars of a semiconductor memory device 130 according to the present embodiment. Illustration of a barrier metal is omitted.

With the semiconductor memory device 130 according to the present embodiment as well, the semiconductor memory device with improved reliability can be provided.

### Fifth Embodiment

A semiconductor memory device according to the present embodiment differs from the first to fourth embodiments in that the connection unit 50 is not provided. Here, description of contents overlapping with those of the first to fourth embodiments is omitted.

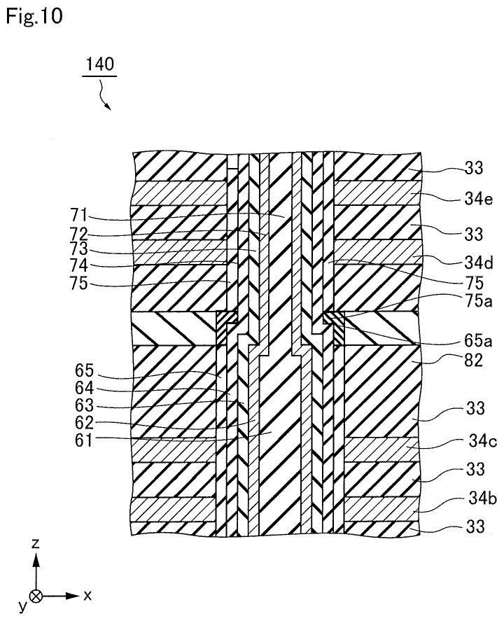

FIG. 10 is a schematic cross-sectional view of the vicinity of the memory pillars of a semiconductor memory device 140 according to the present embodiment. The first core member 61 and the second core member 71 are directly connected. The first signal line 62 and the second signal line 72 are directly connected. The first tunnel insulating film 63 and the second tunnel insulating film 73 are directly connected. The first charge storage film 64 and the second charge storage film 74 are directly connected. The first block insulating film 65 and the second block insulating film 75 are directly connected. Illustration of a barrier metal is omitted. In the first portion 65a of the first block insulating film 65 in contact with the second insulating layer 82, the second insulating material is mixed. Also, in the second portion 75a of the second block insulating film 75 in contact with the first portion 65a, the second insulating material is mixed.

Providing the second insulating layer 82 enables the memory pillar 70 to be formed above the memory pillar 60 without the need to provide the connection unit 50. For this reason, the third signal line 52 is removed, a path of current flowing through the first signal line 62 and the second signal line 72 can be shortened, and the amount of current flowing through the signal line can thus be increased. Further, since a portion at which the conductive layer 34 is away from the first charge storage film 64 and the second charge storage film 74 is reduced in size, a strong electric field can easily be applied to the memory cell.

With the semiconductor memory device 140 according to the present embodiment as well, the semiconductor memory device with improved reliability can be provided.

### Sixth Embodiment

A semiconductor memory device according to the present embodiment differs from the fifth embodiment in that the second insulating layer 82 and the upper surface of the conductive layer 34c are in contact with each other. Here, description of contents overlapping with those of the first embodiment is omitted.

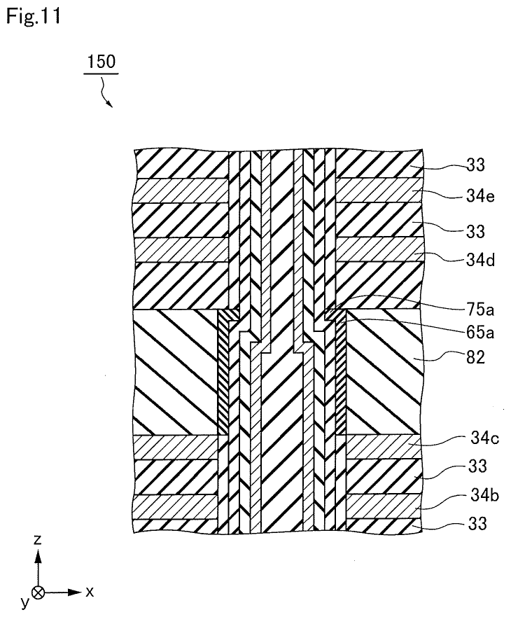

FIG. 11 is a schematic cross-sectional view of the vicinity of the memory pillars of a semiconductor memory device 150 according to the present embodiment. Illustration of a barrier metal is omitted.

With the semiconductor memory device 150 according to the present embodiment as well, the semiconductor memory device with improved reliability can be provided.

### Seventh Embodiment

A semiconductor memory device according to the present embodiment differs from the fifth and sixth embodiments in that the second insulating layer 82 and the second block insulating film 75 are in contact with each other, and in that the second insulating material is mixed in the second portion 75a of the second block insulating film 75 in contact with the second insulating layer 82. Here, description of contents overlapping with those of the first and second embodiments is omitted.

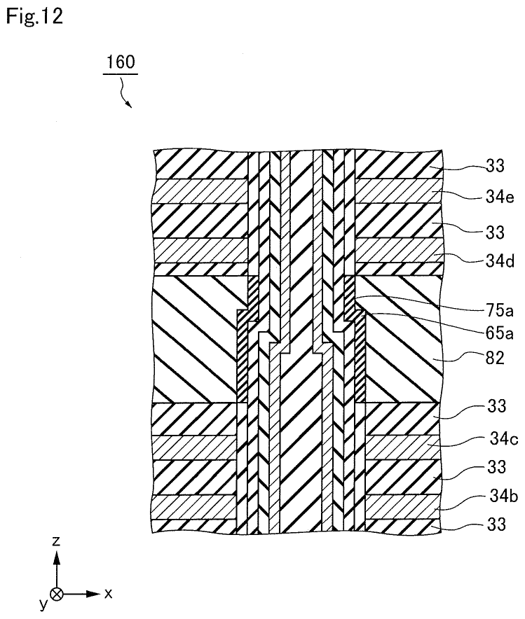

FIG. 12 is a schematic cross-sectional view of the vicinity of the memory pillars of a semiconductor memory device 160 according to the present embodiment. Illustration of a barrier metal is omitted.

With the semiconductor memory device 160 according to the present embodiment as well, the semiconductor memory device with improved reliability can be provided.

### Eighth Embodiment

A semiconductor memory device according to the present embodiment differs from the fifth to seventh embodiments in that the second insulating layer 82 and the upper surface of the conductive layer 34d are in contact with each other. Here, description of contents overlapping with those of the fifth to seventh embodiments is omitted.

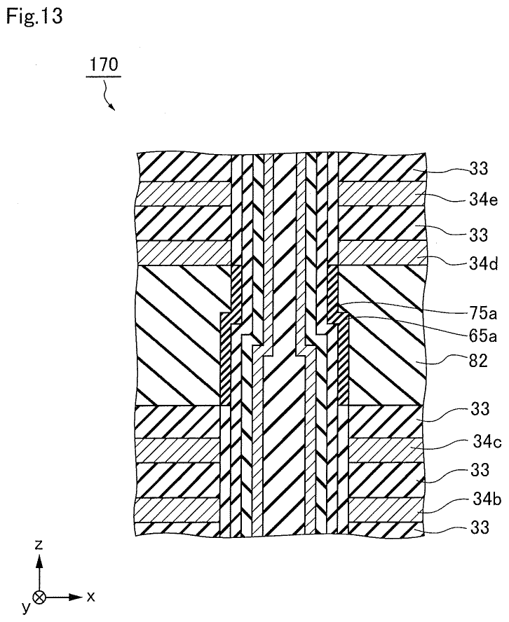

FIG. 13 is a schematic cross-sectional view of the vicinity of the memory pillars of a semiconductor memory device 170 according to the present embodiment. Illustration of a barrier metal is omitted.

With the semiconductor memory device 170 according to the present embodiment as well, the semiconductor memory device with improved reliability can be provided.

While certain embodiments have been described, these embodiments have been presented by way of example only, and are not intended to limit the scope of the inventions. Indeed, the semiconductor memory device described herein may be embodied in a variety of other forms; also, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first conductive layer including a first region and a second region;
a second conductive layer disposed above the first conductive layer to be away from the first conductive layer, the second conductive layer being provided across the first region and the second region;
a pillar passing through the first conductive layer and the second conductive layer in a first direction in the second region, the pillar including a semiconductor film;
a charge storage film provided between the semiconductor film and the first conductive layer and between the semiconductor film and the second conductive layer;
a first insulating layer provided between the first conductive layer and the second conductive layer in the first region, the first insulating layer containing a first insulating material, the first insulating material being silicon oxide;
a second insulating layer provided between the first conductive layer and the second conductive layer in the second region, the second insulating layer containing a second insulating material having a higher dielectric constant than a dielectric constant of the silicon oxide;
a dividing film configured to divide the first conductive layer, the second conductive layer, the first insulating layer, and the second insulating layer in a second direction intersecting with the first direction across the first region and the second region; and
a third insulating layer provided between the dividing film and the second insulating layer, the third insulating layer containing the first insulating material, the third insulating layer being in contact with the first insulating layer.

2. The semiconductor memory device according to claim 1, further comprising an insulating film provided between the second insulating layer and the charge storage film, wherein the second insulating material is mixed in the insulating film.

3. The semiconductor memory device according to claim 1, further comprising an insulating film provided between the second insulating layer and the charge storage film, the insulating film containing the second insulating material.

4. The semiconductor memory device according to claim 1, wherein the second insulating layer is in contact with the first conductive layer.

5. The semiconductor memory device according to claim 1, wherein the second insulating layer is in contact with the second conductive layer.

6. The semiconductor memory device according to claim 1, wherein the pillar includes a first pillar portion passing through the first conductive layer, a second pillar portion passing through the second conductive layer, and a third pillar portion provided between the first pillar portion and the second pillar portion, the third pillar portion having a longer diameter than a diameter of the first pillar portion and a diameter of the second pillar portion.

7. The semiconductor memory device according to claim 6, wherein the diameter of the first pillar portion is longer than the diameter of the second pillar portion.

8. A semiconductor memory device comprising:
a first conductive layer;
a second conductive layer disposed above the first conductive layer;
a first pillar portion passing through the first conductive layer in a first direction, the first pillar portion including a first semiconductor film;
a second pillar portion provided above the first pillar portion, the second pillar portion passing through the second conductive layer in the first direction, the second pillar portion including a second semiconductor film, the second pillar portion being connected to the first pillar portion between the first conductive layer and the second conductive layer in the first direction;
a first charge storage film provided between the first semiconductor film and the first conductive layer;
a second charge storage film provided between the second semiconductor film and the second conductive layer;
a second insulating layer provided between the first conductive layer and the second conductive layer, the second insulating layer containing a second insulating material having a higher dielectric constant than a dielectric constant of a first insulating material, the first insulating material being silicon oxide; and
an insulating film provided between the first charge storage film and the second insulating layer or between the second charge storage film and the second insulating layer, the insulating film having the second insulating material mixed.

9. The semiconductor memory device according to claim 8, further comprising a third pillar portion provided between the first pillar portion and the second pillar portion, the third pillar portion having a longer diameter than a diameter of the first pillar portion.

10. The semiconductor memory device according to claim 9, wherein the insulating film is further provided between the third pillar portion and the second insulating layer.

11. The semiconductor memory device according to claim 8, further comprising:
a dividing film configured to divide the first conductive layer, the second conductive layer, and the second insulating layer in a second direction intersecting with the first direction; and
a third insulating layer provided between the dividing film and the second insulating layer, the third insulating layer containing the first insulating material.

12. The semiconductor memory device according to claim 8, wherein the second insulating layer is in contact with the first conductive layer.

13. The semiconductor memory device according to claim 8, wherein the second insulating layer is in contact with the second conductive layer.

14. A semiconductor memory device comprising:
a first conductive layer;
a second conductive layer disposed above the first conductive layer;
a first pillar portion passing through the first conductive layer in a first direction, the first pillar portion including a first semiconductor film;
a second pillar portion provided above the first pillar portion, the second pillar portion passing through the second conductive layer in the first direction, the second pillar portion including a second semiconductor film, the second pillar portion being connected to the first pillar portion between the first conductive layer and the second conductive layer in the first direction;
a first charge storage film provided between the first semiconductor film and the first conductive layer;
a second charge storage film provided between the second semiconductor film and the second conductive layer;
a second insulating layer provided between the first conductive layer and the second conductive layer, the second insulating layer containing a second insulating material having a higher dielectric constant than a dielectric constant of a first insulating material, the first insulating material being silicon oxide; and
an insulating film provided between the first charge storage film and the second insulating layer or between the second charge storage film and the second insulating layer, the insulating film containing the second insulating material.

15. The semiconductor memory device according to claim 14, further comprising a third pillar portion provided between the first pillar portion and the second pillar portion, the third pillar portion having a longer diameter than a diameter of the first pillar portion.

16. The semiconductor memory device according to claim 15, wherein the insulating film is further provided between the third pillar portion and the second insulating layer.

17. The semiconductor memory device according to claim 14, further comprising:
a dividing film configured to divide the first conductive layer, the second conductive layer, and the second insulating layer in a second direction intersecting with the first direction; and
a third insulating layer provided between the dividing film and the second insulating layer, the third insulating layer containing the first insulating material.

18. The semiconductor memory device according to claim 14, wherein the second insulating layer is in contact with the first conductive layer.

19. The semiconductor memory device according to claim 14, wherein the second insulating layer is in contact with the second conductive layer.
